(19) United States
(12) Patent Application Publication
(10) Pub. No.: US 2003/0161949 A1
(43) Pub. Date: Aug. 28, 2003

(54) Vapor deposition of dihalodialklysilanes

(75) Inventors: William R. Ashurst, Berkeley, CA (US); Roya Maboudian, Orinda, CA (US); Carlo Carraro, Orinda, CA (US); Wilhelm Frey, Mountain View, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: THE REGENTS OF THE UNIVERSITY OF CALIFORNIA, Oakland, CA

(21) Appl. No.: 10/086,652

(22) Filed: Feb. 28, 2002

(51) Int. Cl. C23C 16/00

(52) U.S. Cl. 427/248.1

(57) ABSTRACT

Coatings of dialkylsilyloxy groups are applied to water-wettable surfaces by chemical vapor deposition using dihalodialkylsilanes with short-chain alkyl groups. Some of the surfaces which will benefit from the application of these coatings are hydroxyl-terminated silicon surfaces of microelectromechanical systems, nanoelectromechanical systems, and biomicroelectromechanical systems, while surfaces of other chemistries will benefit as well. When applied to a microstructure on an MEMS surface, the coating reduces stiction in the microstructure. The use of the vapor phase as a deposition medium facilitates the deposition process and permits close control over the reaction conditions and the characteristics of the resulting coating.

This invention was made with Government support under Grant (Contract) Nos. DM11-0099765 awarded by the National Science Foundation. The Government has certain rights to this invention.

BACKGROUND OF THE INVENTION

1. Field of the Invention

This invention resides in the fields of anti-stiction coatings on various types of surfaces, including those of micromechanical and microelectromechanical systems, as well as biomicroelectromechanical systems, microfluidics systems, and nanoelectromechanical systems.

2. Description of the Prior Art

Micromechanical and microelectromechanical systems, commonly referred to in the industry by the acronym MEMS, are miniaturized devices that contain electronic components as well as gear trains, motors, valves, and other components analogous to conventional macro-scale machinery but with sub-millimeter dimensions. MEMS devices are used in many different applications and the number continues to grow as the many capabilities of these devices become known. Nanoelectromechanical systems (NEMS) are similar to MEMS but on an even smaller scale. Biomicroelectromechanical systems (bioMEMS) are systems on the micro- or nano- scale that incorporate biological or biochemical elements such as neurons, nucleic acids, polypeptides, and the like, and microfluidics systems involve liquid movement or contact on a microscale.

MEMS devices, which are illustrative of the different types of devices to which the present invention applies, generally have a large surface-to-volume ratio which makes these devices susceptible to stiction, a term that refers to the unintentional adhesion of compliant surfaces due capillary forces, van der Waals forces, and electrostatic attraction. Stiction occurs in two forms—release stiction and in-use stiction. Release stiction arises during the release step, which is the removal of the sacrificial layers between which MEMS devices are initially prepared. The removal of these layers releases the microstructures included on the MEMS to render them functional. In the typical release step, the sacrificial layers are removed by etching, followed by rinsing to remove the etchant. The rinse liquid introduces stiction-causing capillary forces to the microstructures. These forces tend to cause warpage of the microstructures as they are released, and the distortion may become fixed into the structure by solid bridges that are formed during the subsequent evaporative drying. In-use stiction is also caused by capillary forces, as well as van der Waals forces and electrostatic forces that arise along the surfaces of microstructures and the supporting substrate. As microstructures become more sophisticated and complex, both types of stiction become increasingly problematic and many MEMS devices fail for this reason.

Efforts to control stiction have included modifications to the topography of the contacting surfaces as well as modifications to the chemical composition of the surfaces. Modifications to the chemical composition offer the advantage of not altering the microstructures. One type of chemical modification is the formation of a self-assembled monolayer (SAM) on the surface. The published literature contains descriptions of the use of SAMs on MEMS devices that contain microfabricated cantilever beams on polycrystalline silicon, the SAMs serving to alleviate release-rated stiction and as a post-release anti-stiction lubricant. See Alley, R. L., et al., “The Effect of Release-Etch Processing on Surface Microstructure Stiction,” Proc. IEEE Solid State Sensor and Actuator Workshop, 202-207 (1992). Further use of SAMs is reported by Houston, M. R., et al., “Self-Assembled Monolayer Films as Durable Anti-Stiction Coatings for Polysilicon Microstructures,” Technical Digest of the Solid-State Sensor and Actuator Workshop, 42-47 (1996). The Houston et al. paper describes a procedure by which the SAM is applied as part of the microstructure release process.

The SAM precursor used by both Alley et al. and Houston et al. was octadecyltrichlorosilane (OTS). This precursor forms a hydrophobic monolayer on the substrate by an HCl elimination reaction which results in the covalent bonding of an octadecylsilyloxy group to silicon atoms on the substrate surface. Other precursors that have been used to a similar effect are 1H, 1H, 2H, 2H-perfluorodecyltrichlorosilane (FDTS), and tridecafluoro-1,1,2,2-tetrahydrooctyltrichlorosilane (FOTS). Deposition of the SAM has been performed in both the liquid phase and the vapor phase. Vapor-phase deposition of FOTS utilizing an ultrahigh vacuum (UHV) chamber is reported by Mayer, T. M., et al., “Chemical Vapor Deposition of Fluoroalkylsilane Monolayer Films for Adhesion Control in Microelectromechanical Systems,” J. Vac. Sci. Technol. B 18(5):2433-2440 (2000).

Precursor silanes with two short alkyl chains have also been used, notably dichlorodimethylsilane, dichlorodiethylsilane, and dichlorodipropylsilane, as reported by Oh, C.-H., et al., “A New Class of Surface Modification for Stiction Reduction,” Proceedings of the 10th International Conference on Solid-State Sensors and Actuators, Sendai, Japan, June 1999, pp. 30-33, and dichlorodimethylsilane alone by Kim, B.-H., et al., “A New Class of Surface Modifiers for Stiction Reduction,” Proceedings of MEMS ′99, Orlando, Fla., January 1999, pp. 189-193. Application of the monolayers in each case was achieved by the use of an organic solution of the precursor. The disclosures of each of the citations listed in this section are incorporated herein by reference in their entirety.

### SUMMARY OF THE INVENTION

It has now been discovered that self-assembled monolayers or coatings in general can be formed on surfaces that are at least partially wettable by water, in a highly effective and efficient manner without the use of stringent operating conditions. This is accomplished by the vapor-phase deposition of a precursor dihalodialkylsilane with short alkyl chains. Monolayers as well as thicker coatings can be formed by this method on surfaces of hydroxyl-terminated silicon as well as those of other materials, such as for example metal oxides, silicon nitride, glass, steel and alumina. When applied to MEMS devices and the other micro- and nano-scale devices referred to above, the coating is effective in reducing both release-induced stiction and use-related stiction. This discovery offers the advantage of permitting the use of a relatively moderate vacuum as compared to the higher vacuums required with precursor. silanes with longer alkyl groups. A moderate vacuum allows one to use much simpler coating equipment with a-lower maintenance requirement. A further advantage is the elimination of the need for solvents and the problems of waste handling that solvents often cause. Performance of the procedure in the vapor phase also eliminates many of the difficulties associated with liquid handling and mass transport in liquid systems. In preferred embodiments, water vapor is included in the vapor phase, and use of the vapor phase permits closer control over the amount of water present. This affects the reactions taking place during deposition, including the selectivity toward monolayer deposition over polymerization of the silane. The deposition process of this invention lends itself well to large-scale surfaces as opposed to previous methods which have been effective only on small samples, typically on the order of 1 cm². The process of this invention makes it possible to perform effective deposition on whole wafers of any size as well as on cassettes of wafers.

These and other features, advantages, implementations, and embodiments of the invention will be better understood from the description that follows.

### DETAILED DESCRIPTION OF THE INVENTION AND PREFERRED EMBODIMENTS

Alkyl-substituted and halogen-substituted silanes, including those contemplated for use in the present invention, are readily available from commercial chemicals suppliers. In the dihalodi(C₁-C₃ alkyl)silanes used in the practice of this invention, the alkyl groups are saturated and unsubstituted and the two alkyl groups bonded to a single silicon atom are either the same or different, as are the two halo atoms. Preferred alkyl groups are unbranched. The halo atoms are preferably bromine, chlorine or fluorine, with chlorine particularly preferred. Some of the preferred dihalodi(C₁-C₃ alkyl)silanes within the scope of this invention are dichlorodimethylsilane, dichlorodiethylsilane, and dichlorodipropylsilane. Dichlorodimethylsilane is particularly preferred.

The deposition process by which the coating is applied is preferably performed in the presence of a small and controlled amount of moisture. Performing the deposition in the vapor phase permits one to achieve such control with relative ease. While the amount of moisture can vary, best results will be obtained in most cases by using water vapor at a partial pressure of from about 0.5 torr to about 10.0 torr, and preferably from about 1.0 torr to about 5.0 torr. The process is also preferably performed in the absence of organic solvents.

The partial pressure of the dihalodi(C₁-C₃ alkyl)silane can likewise vary, and optimal amounts will depend on the choice of dihalodi(C₁-C₃ alkyl)silane used. Higher molecular weight silanes within the class are preferably applied at lower partial pressures. In most cases, however, the partial pressure of the silane will range from about 0.5 torr to about 5.0 torr, and preferably from about 1.0 torr to about 3.0 torr. The total pressure of these gases can likewise vary from as low as 10⁻¹² torr to as high as 100 torr, but preferably from about 0.1 torr to about 15.0 torr, and preferably from about 1.0 torr to about 5.0 torr.

In embodiments of the invention that include exposure of the surface to water vapor in addition to the gaseous silane, the substrate is exposed to the silane and the water vapor simultaneously, although the exposure can begin with either one in the absence of the other, particularly for purposes of facilitating the control and measurement of the partial pressures.

The deposition process is also preferably performed in a non-oxidizing atmosphere. To accomplish this, the atmosphere surrounding the substrate can be purged with a nonoxidizing gas prior to exposure of the substrate to the silane. The non-oxidizing gas is preferably a gas that is either generally inert or one that does not react with the silane, the water vapor, or the substrate. Purging with the inert or nonreactive gas can be repeated after the silane/water vapor exposure as a means of quenching the reaction. The purge gas is preferably an inorganic gas, and most preferably an inert gas such as nitrogen or argon. A small amount of the purge gas will in most cases be retained in the gas mixture contacting the substrate during the reaction, but this retained gas is generally insignificant in amount.

The temperature at which the exposure takes place is not critical and can vary. The exposure is preferably performed at room (ambient) temperature or slightly above, however, and preferred temperatures are those within the range of from about 0° C. to about 85° C., most preferably from about 15° C. to about 50° C.

The exposure can be performed in a single stage or in two or more stages with evacuation between each stage. The exposure time in any single stage should be sufficient to form a monolayer but not so long as to allow a significant amount of polymerization of the reagent to occur. With these considerations in mind, the exposure time will preferably range from about 3 minutes to about 30 minutes, and most preferably from about 10 minutes to about 20 minutes.

Surfaces to which the present invention is applicable are those that are partially or completely wettable by water, i.e., surfaces that have a water contact angle of less than 90°. Many such surfaces are considered by those skilled in the art to be “hydrophilic.” In addition, many such surfaces, including some that are hydrophilic, are surfaces with exposed hydroxyl groups such as hydroxyl-terminated silicon and particularly hydroxyl-terminated polysilicon which are of interest in MEMS and MEMS-related devices. Further examples of water-wettable surfaces useful in MEMS and MEMS-related technology are metal oxides, examples of which are copper oxides and gold oxides. Still further examples of surfaces to which the present invention is applicable are silicon nitride, glass, steel, and alumina. Others will be apparent to those skilled in the art. Surfaces with exposed hydroxyl groups can be achieved by methods well known to those skilled in the art, particularly those knowledgeable in MEMS manufacture and use.

MEMS devices and other devices with micro-scale and nano-scale structures that are newly manufactured and yet to be installed in larger equipment or apparatus typically contain sacrificial layers that serve a protective function. These sacrificial layers are removed by either liquid or dry methods. Liquid methods include an acid etch, typically hydrofluoric acid or a mixture of hydrofluoric and hydrochloric acids, while an example of a dry method is the use of vapor-phase hydrofluoric acid. In either case, the hydroxyl-terminated form is typically achieved by subsequent treatment with a peroxide. These procedures are in current commercial use and the concentrations and operating conditions will generally be the same in the practice of the present invention.

The adherence of the silane coating to the substrate surface, whether the substrate be silicon, polysilicon, glass, alumina, silicon nitride, steel, or any other material, is not fully understood and may be achieved by covalent bonding or by hydrogen bonding, particularly when the surface contains a residual layer of water molecules, or other means of adherence. Although not intending to be bound by any particular theory, it is believed that at least in most cases covalent bonding plays a significant role in the adherence, with some or all of the silane groups either covalently bonded directly to the surface or with many of the silane groups bonded to each other and some bonded to the surface as well.

The following example is offered as an illustration of the practice of this invention, and is not intended to impose limitations on the scope of the invention.

### EXAMPLE

Test chips having cantilever beam array microstructures, each array containing beams that range from 150 μm to 900 μm in 50- μm increments, that had been released by treatment with liquid HF/HCl, followed by critical point drying, were placed in a vacuum chamber. In the chamber, the chips were exposed to an in-situ DC oxygen plasma, followed by in-situ DC water plasma. The chamber pressure was then lowered by a mechanical vacuum pump to a pressure of less than 10⁻² torr. Water vapor was then introduced into the chamber until the total pressure in the chamber was about 5.0 torr. The chamber pressure was once again lowered, this time to a pressure of about 1.0 torr. Dichlorodimethylsilane (DDMS) vapor was then admitted to the chamber, raising the pressure by about 1.5 torr. The resulting gas mixture was maintained in the chamber for ten minutes, then evacuated to less than 10⁻² torr. The chamber was then vented with dry nitrogen gas, and the chips removed for analysis.

The analysis was done by the performance of adhesion tests on the cantilever beam arrays in accordance with known testing methods, as described by Mastrangelo, C. H., “Adhesion-related failure mechanisms in micromechanical devices,” Tribology Letters 3: 223-238 (1997), incorporated herein by reference. The test results indicated detachment lengths averaging 510 μm which is equivalent to an apparent work of adhesion of 62 μJ/m². The corresponding apparent work of adhesion for a liquid-based process using the same precursor was 45 μJ/m², as reported by Ashurst, W. R., et al., “Dichloromethylsilane as an Anti-Stiction Monolayer for MEMS: A Comparison to the Octadecyltrichlorosilane Self Assembled Monolayer,” J. Microelectromechanical Sys. 10(1): 41-49 (2001), also incorporated herein by reference.

The foregoing is offered primarily for purposes of illustration. Further variations, modifications and substitutions beyond those mentioned herein that still embody the central features and concepts of the invention will be readily apparent to those skilled in the art.

What is claimed is:

1. A method for applying a silane coating to a surface that is at least partially wettable by water, said method comprising exposing said surface to a vapor-phase dihalodi(C₁-C₃ alkyl)silane, under conditions resulting in the bonding of di(C₁-C₃ alkyl)silyloxy groups to said surface.

2. A method in accordance with claim 1 in which said dihalodi(C₁-C₃ alkyl)silane is di(C₁-C₃ alkyl)dichlorosilane.

3. A method in accordance with claim 1 in which said dihalodi(C₁-C₃ alkyl)silane is dimethyldichlorosilane.

4. A method in accordance with claim 1 in which said surface is a hydrophilic surface.

5. A method in accordance with claim 1 in which said surface is a member selected from the group consisting of hydroxyl-terminated silicon, silicon nitride, glass, steel, alumina, oxides of copper, and oxides of gold.

6. A method in accordance with claim 1 in which said surface is hydroxyl-terminated polysilicon.

7. A method in accordance with claim 1 further comprising exposing said surface to water vapor while exposing said surface to said vapor-phase dihalodi(C₁-C₃ alkyl)silane.

8. A method in accordance with claim 1 in which said exposure to said vapor-phase dihalodi(C₁-C₃ alkyl)silane is performed in a non-oxidizing atmosphere.

9. A method in accordance with claim 1 comprising exposing said surface to a gaseous mixture consisting of said dichlorodi(C₁-C₃ alkyl)silane, water vapor and an inert gas.

10. A method in accordance with claim 1 comprising exposing said surface to a gaseous mixture consisting of said dichlorodimethylsilane, water vapor and molecular nitrogen.

11. A method in accordance with claim 1 in which said vapor-phase dihalodi(C₁-C₃ alkyl)silane is at a partial pressure of from about 0.5 torr to about 5.0 torr.

12. A method in accordance with claim 1 in which said dihalodi(C₁-C₃ alkyl)silane is dichlorodimethylsilane and is at a partial pressure of from about 1.0 torr to about 3.0 torr.

13. A method in accordance with claim 1 in which said exposure is performed at a total pressure of from about 0.1 torr to about 15 torr.

14. A method in accordance with claim 1 in which said exposure is performed at a total pressure of from about 1 torr to about 5 torr.

15. A method in accordance with claim 1 in which said exposure is performed at a temperature of from about 0° C. to about 85° C.

16. A method in accordance with claim 1 in which said exposure is performed at a temperature of from about 15° C. to about 50° C.

17. A method in accordance with claim 1 in which said exposure is performed for a continuous exposure time of from about 3 minutes to about 30 minutes.

18. A method in accordance with claim 1 in which said exposure is performed for a continuous exposure time of from about 10 minutes to about 20 minutes.
